(19) United States
(12) Patent Application Publication
(10) Pub. No.: US 2025/0062186 A1
(43) Pub. Date: Feb. 20, 2025

(54) SEMICONDUCTOR PACKAGE

(71) Applicant: Samsung Electronics Co., Ltd., Suwon-si (KR)

(72) Inventor: Junghoo Yun, Suwon-si (KR)

(21) Appl. No.: 18/636,447

(22) Filed: Apr. 16, 2024

(30) Foreign Application Priority Data
Aug. 17, 2023 (KR) 10-2023-0107918

(51) Int. Cl. H01L 23/42; H01L 23/00; H01L 23/31; H01L 23/367; H01L 23/373; H01L 23/498; H01L 23/538; H01L 23/64; H01L 25/10

(52) U.S. Cl. CPC H01L 23/42; H01L 23/3128; H01L 23/367; H01L 23/3736; H01L 23/49811; H01L 23/5385; H01L 23/642; H01L 24/16; H01L 24/32; H01L 24/73; H01L 25/105; H01L 2224/16227; H01L 2224/32195; H01L 2224/73253

(57) ABSTRACT

A semiconductor package is provided. The semiconductor package includes a lower redistribution structure, a semiconductor chip on a top surface of the lower redistribution structure, a plurality of conductive posts on a top surface of the lower redistribution structure and spaced apart from the semiconductor chip in a direction parallel to the top surface of the lower redistribution structure, a plurality of capacitors arranged on the top surface of the lower redistribution structure, the plurality of capacitors being between the semiconductor chip and the plurality of conductive posts, and a plurality of thermal interface material layers between the semiconductor chip and the plurality of capacitors.

### CROSS-REFERENCE TO RELATED APPLICATION

This application is based on and claims priority under 35 U.S.C. § 119 to Korean Patent Application No. 10-2023-0107918, filed on Aug. 17, 2023, in the Korean Intellectual Property Office, the disclosure of which is incorporated by reference herein in its entirety.

### BACKGROUND

Embodiments of the inventive concept relate to a semiconductor package.

In accordance with the recent rapid development of the electronics industry and the demands of users, electronic devices are becoming more compact, multifunctional, and large-capacity, and accordingly, highly integrated semiconductor chips are desired. As a result, a semiconductor package that has secured connection reliability while including a highly integrated semiconductor chip with an increased number of connection terminals for input/output (I/O) is being designed.

### SUMMARY

The inventive concept provides a semiconductor package with improved operational reliability and heat dissipation characteristics.

According to an aspect of the inventive concept, there is provided a semiconductor package including a lower redistribution structure; a semiconductor chip on a top surface of the lower redistribution structure; a plurality of conductive posts on a top surface of the lower redistribution structure and spaced apart from the semiconductor chip in a direction parallel to the top surface of the lower redistribution structure; a plurality of capacitors on the top surface of the lower redistribution structure, the plurality of capacitors being between the semiconductor chip and the plurality of conductive posts; and a plurality of thermal interface material layers between the semiconductor chip and the plurality of capacitors.

According to another aspect of the inventive concept, there is provided a semiconductor package including a lower redistribution structure; a semiconductor chip on a top surface of the lower redistribution structure; a plurality of conductive posts on the top surface of the lower redistribution structure and spaced apart from the semiconductor chip in a direction parallel to the top surface of the lower redistribution structure; a plurality of capacitors on the top surface of the lower redistribution structure, the plurality of capacitors being between the semiconductor chip and the plurality of conductive posts; a plurality of thermal interface material layers between the semiconductor chip and the plurality of capacitors; an upper redistribution structure on the conductive posts; and a plurality of thermal vias in the upper redistribution structure and connected to the plurality of capacitors, wherein an area of the semiconductor chip in a plan view is smaller than an area of the lower redistribution structure in the plan view.

According to another aspect of the inventive concept, there is provided a semiconductor package including a lower redistribution structure; a semiconductor chip on a top surface of the lower redistribution structure; a plurality of conductive posts on a top surface of the lower redistribution structure and spaced apart from the semiconductor chip in a first horizontal direction parallel to the top surface of the lower redistribution structure or in a second horizontal direction perpendicular to the first horizontal direction; a plurality of capacitors on the top surface of the lower redistribution structure, the plurality of capacitors being between the semiconductor chip and the plurality of conductive posts; a plurality of thermal interface material layers between the semiconductor chip and the plurality of capacitors; a plurality of chip connection terminals between the lower redistribution structure and the semiconductor chip and between the lower redistribution structure and the plurality of capacitors; a molding layer covering the top surface of the lower redistribution structure, the molding layer surrounding the semiconductor chip, the plurality of conductive posts, the plurality of capacitors, the plurality of thermal interface material layers, and the plurality of chip connection terminals; an upper redistribution structure on the conductive posts; a plurality of thermal vias in the upper redistribution structure, the plurality of thermal vias being connected to the plurality of capacitors, a heat dissipation contact on a top surface of the upper redistribution structure; and a heat dissipation part on a top surface of the heat dissipation contact, wherein heat generated from the semiconductor chip is transferred sequentially along the plurality of thermal interface material layers, the plurality of capacitors, the plurality of thermal vias, the heat dissipation contact, and the heat dissipation part, an area of the semiconductor chip in a plan view is smaller than an area of the lower redistribution structure in the plan view, the plurality of thermal interface material layers surround at least part of horizontal edges of the semiconductor chip, an uppermost end of each of the plurality of thermal interface material layers is on a same plane as or above a top surface of the semiconductor chip in a vertical direction, and a lowermost end of each of the plurality of thermal interface material layers is on a same plane as or below a bottom surface of the semiconductor chip in the vertical direction.

### BRIEF DESCRIPTION OF THE DRAWINGS

Embodiments of the inventive concept will be more clearly understood from the following detailed description taken in conjunction with the accompanying drawings in which:

FIG. 1 is a cross-sectional view of a semiconductor package according to an embodiment;

FIG. 2A is a schematic plan view of a semiconductor package according to an embodiment;

FIG. 2B is a plan view schematically illustrating a semiconductor package according to another embodiment;

FIG. 2C is a plan view schematically illustrating a semiconductor package according to another embodiment;

FIG. 3 is a cross-sectional view schematically illustrating a semiconductor package according to another embodiment; and

FIGS. 4 to 15 are cross-sectional views illustrating a method of manufacturing a semiconductor package according to a process sequence, according to an embodiment.

### DETAILED DESCRIPTION OF THE EMBODIMENTS

Since the present embodiments may be modified in various ways and may have various forms, some embodiments are illustrated in the drawings and described in detail. However, it is not intended to limit the present embodiments to the particular disclosed forms. In addition, embodiments described below are merely illustrative, and various modifications are possible from these embodiments.

The use of all examples or example terms is merely intended to describe the technical idea in detail and is not intended to be limiting in scope by such examples or example terms, unless being limited by the claims.

It will be understood that, although the terms first, second, third etc. may be used herein to describe various elements, components, regions, layers and/or sections, these elements, components, regions, layers and/or sections should not be limited by these terms. Unless the context indicates otherwise, these terms are only used to distinguish one element, component, region, layer or section from another element, component, region, layer or section, for example as a naming convention. Thus, a first element, component, region, layer or section discussed below in one section of the specification could be termed a second element, component, region, layer or section in another section of the specification or in the claims without departing from the teachings of the present invention. In addition, in certain cases, even if a term is not described using “first,” “second,” etc., in the specification, it may still be referred to as “first” or “second” in a claim in order to distinguish different claimed elements from each other.

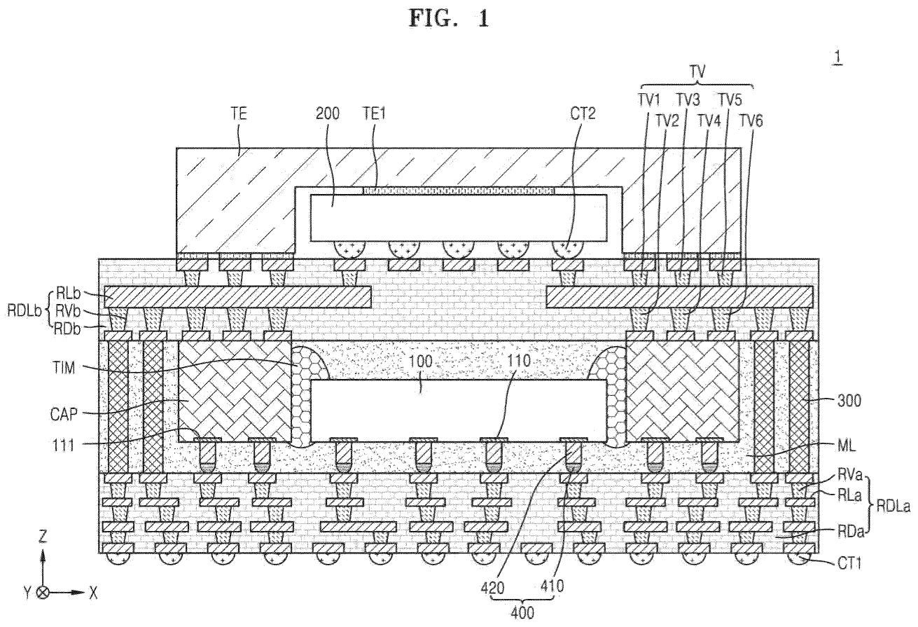

FIG. 1 is a cross-sectional view of a semiconductor package according to an embodiment.

Referring to FIG. 1, a semiconductor package 1 includes: a lower redistribution structure RDLa; a semiconductor chip 100 arranged on a top surface of the lower redistribution structure; a plurality of conductive posts 300 arranged on a top surface of the lower redistribution structure RDLa and spaced apart from the semiconductor chip 100 in a direction parallel to the top surface of the lower redistribution structure RDLa; a plurality of capacitor structures (e.g., capacitors) CAP arranged on the top surface of the lower redistribution structure RDLa and arranged between the semiconductor chip 100 and the plurality of conductive posts 300; and a plurality of thermal interface material layers TIM arranged between the semiconductor chip 100 and the plurality of capacitor structures CAP; and a plurality of chip connection terminals 400 arranged between the lower redistribution structure RDLa and the first semiconductor chip 100, and arranged between the lower redistribution structure RDLa and the plurality of capacitor structures CAP. The plurality of chip connection terminals 400 each may include a lower pillar 410 electrically connected to the lower redistribution structure RDLa, and a conductive cap 420 arranged between the lower pillar 410 and the first semiconductor chip 100 and electrically connecting the semiconductor chip 100 with the lower pillar 410. The lengths, thicknesses, and shapes of the lower pillar 410 and the conductive cap 420 are not limited to those shown in the drawings.

The semiconductor package 1 may include a molded layer ML covering a top surface of the lower redistribution structure RDLa and enclosing the semiconductor chip 100, the plurality of conductive posts 300, the plurality of capacitor structures CAP, and the plurality of thermal interface material layers TIM. The molding layer ML may fill spaces among the plurality of conductive posts 300.

It will be understood that when an element is referred to as “contacting” or “in contact with” another element (or using any form of the word “contact”), there are no intervening elements present at the point of contact.

The first semiconductor chip 100 may include a plurality of semiconductor chip pads 110 arranged at portions where the first semiconductor chip 100 chip and the plurality of conductive caps 420 are in contact with each other. A plurality of connection pads 111 may be arranged at portions where the plurality of capacitor structures CAP and the plurality of conductive caps 420 are in contact with each other. The numbers, shapes, and thicknesses of the semiconductor chip pads 110 and the connection pads 111 are not limited to those shown in the drawings.

The semiconductor package 1 may include the first semiconductor chip 100, the lower redistribution structure RDLa, the molding layer ML, an upper redistribution structure RDLb, and a second semiconductor chip 200. The semiconductor package 1 may also include the plurality of thermal interface material layers TIM abutting the first semiconductor chip 100, the plurality of capacitor structures CAP in contact with the thermal interface material layers TIM, and the plurality of conductive posts 300 arranged spaced apart from the capacitor structures CAP. Although the conductive posts 300 appear to be arranged in a row in FIG. 1, the conductive posts 300 may be arranged in a plurality of rows. The conductive post 300 may be electrically connected to the lower redistribution structure RDLa. The conductive post 300 may electrically connect the lower redistribution structure RDLa with the upper redistribution structure RDLb.

Hereinafter, unless particularly defined, directions parallel to the top surface of the lower redistribution structure RDLa and perpendicular to each other are defined as a first horizontal direction X and a second horizontal direction Y, and a direction perpendicular to the top surface of the lower redistribution structure RDLa is defined as a vertical direction Z. That is, the vertical direction Z is a direction perpendicular to the first horizontal direction X and the second horizontal direction Y.

The first semiconductor chip 100 of the semiconductor package 1 may include an active surface and an inactive surface opposite to the active surface. In some embodiments, the first semiconductor chip 100 may be arranged on the top surface of the lower redistribution structure RDLa so that the active surface faces the lower redistribution structure RDLa, and the first semiconductor chip 100 may include a semiconductor chip pad 110 at a lower end portion in a vertical direction facing the lower redistribution structure RDLa. The semiconductor chip pad 110 may be electrically connected to individual elements on the active surface of the first semiconductor chip 100, and the chip pad 110 may be electrically connected to the lower redistribution structure RDLa through the chip connection terminal 400.

The lower redistribution structure RDLa of the semiconductor package 1 may include a plurality of lower wiring layers RLa, a plurality of lower vertical vias RVa vertically connecting the plurality of lower wiring layers RLa to each other, and a lower insulating layer RDa surrounding the lower vertical via Rva. The upper redistribution structure RDLb may include a plurality of upper wiring layers RLb, a plurality of upper vertical vias RVb vertically connecting the plurality of upper wiring layers RLb to each other, and an upper insulating layer RDb surrounding the upper vertical vias RVb.

The lower insulating layer RDa may be made of at least one material selected from phenol resin, epoxy resin, and polyimide. For example, the lower insulating layer Rda may include at least one material selected from flame retardant 4 (FR4), tetrafunctional epoxy, polyphenylene ether, epoxy/polyphenylene oxide, bismaleimide triazine (BT), Thermount, Cyanate ester, polyimide and liquid crystal polymer.

The lower vertical via RVa may be formed of or include copper (Cu) or an alloy including copper (Cu). For example, the lower vertical via RVa may have a structure in which copper (Cu) or an alloy including copper (Cu) is stacked on a seed layer including copper (Cu), titanium (Ti), titanium tungsten (TiW), titanium nitride (TiN), tantalum (Ta), tantalum nitride (TaN), chromium (Cr), Cu+Ti in which copper is stacked on titanium, or Cu/TiW on which copper is stacked on titanium tungsten, but is not limited thereto. In some embodiments, the lower vertical via RVa may be formed to cover an inner sidewall of a via through hole penetrating the lower insulating layer RDa and fill a part of the via through hole.

The lower wiring layer RLa may be formed of or include an electrolytically deposited (ED) copper foil, a rolled-annealed (RA) copper foil, stainless steel foil, aluminum foil, ultra-thin copper foils, sputtered copper, copper alloys, etc.

A semiconductor substrate (not shown) including the first semiconductor chip 100 may be formed of or include, for example, a semiconductor material such as silicon (Si) or germanium (Ge). Alternatively, the semiconductor substrate may include a compound semiconductor material, such as silicon carbide (SiC), gallium arsenide (GaAs), indium arsenide (InAs), and indium phosphide (InP). The semiconductor substrate may include, for example, a well doped with impurities as a conductive region. The semiconductor substrate may have various device isolation structures such as a shallow trench isolation (STI) structure.

The first semiconductor chip 100 may include a conductive region, for example, an impurity-doped well or an impurity-doped structure. A semiconductor device layer including individual elements may be provided on the active surface of the first semiconductor chip 100. The individual elements may include, for example, transistors. The individual elements may include microelectronic devices such as image sensors, metal-oxide-semiconductor field effect transistors (MOSFET), system large scale integration (LSI), and CMOS imaging sensors (CIS), micro-electro-mechanical systems (MEMS), active devices, passive devices, etc.

The first semiconductor chip 100 may be a memory chip or a logic chip. The memory chip may be, for example, a volatile memory chip such as dynamic random access memory (DRAM) or static random access memory (SRAM), or may be a nonvolatile memory chip such as a phase-change random access memory (PRAM), a magnetoresistive random access memory (MRAM), ferroelectric random access memory (FeRAM), or resistive random access memory (RRAM). The logic chip may be a central processing unit (CPU) chip, a graphics processing unit (GPU) chip, an application processor (AP) chip, or an application specific integrated circuit (ASIC) chip.

In some embodiments, the conductive post 300 may be, for example, a metal, such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Rc), beryllium (Be), gallium (Ga), ruthenium (Ru) or the like, or a metal alloy thereof, but is not limited thereto.

The semiconductor package 1 may include an external connection terminal CT1 positioned on a bottom surface of the lower redistribution structure RDLa. The external connection terminal CT1 may be uniformly arranged on at least a partial region of the bottom surface of the lower redistribution structure RDLa. Accordingly, the external connection terminal CT1 is uniformly stressed from the outside, and cracks generated in some external connection terminals CT1 may be suppressed.

The external connection terminal CT1 may be formed on the bottom surface of the lower redistribution structure RDLa. The external connection terminal CT1 may be formed of or include, for example, a solder ball, a conductive paste, a ball grid array (BGA), a lead grid array (LGA), a pin grid array (PGA), or a combination thereof.

In some embodiments, the lower vertical via RVa structurally arranged inside the lower redistribution structure RDLa may be formed to have a tapered shape in which the width of the first horizontal direction X and/or the width of the second horizontal direction Y gradually increase as it approaches the bottom surface of the first semiconductor chip 100. That is, the horizontal area of the lower vertical via RVa of the lower redistribution structure RDLa may increase with decreasing distance from the first semiconductor chip 100. In addition, the upper vertical via RVb structurally arranged inside the upper redistribution structure RDLb may be formed to have a tapered shape in which the width of the first horizontal direction X and/or the width of the second horizontal direction Y gradually decrease as it approaches the top surface of the first semiconductor chip 100. That is, the horizontal area of the upper vertical via RVb of the upper redistribution structure RDLb may decrease with decreasing distance from the first semiconductor chip 100.

As shown in the drawing, the lower redistribution structure RDLa may have three lower wiring layers RLa and three lower vertical vias RVa, and the upper redistribution structure RDLb may have two upper wiring layers RLb and two upper vertical vias RVb, but is not limited thereto. In addition, the thickness of the lower redistribution structure RDLa in the vertical direction may be greater than that of the upper redistribution structure RDLb in the vertical direction, but is not limited thereto.

The second semiconductor chip 200 may be arranged on the upper redistribution structure RDLb. The second semiconductor chip 200 may have an active surface and an inactive surface opposite to each other. The second semiconductor chip 200 may be formed of or include, for example, silicon (Si). Alternatively, the semiconductor substrate may include a semiconductor element, such as germanium (Ge), or a compound semiconductor, such as silicon carbide (SIC), gallium arsenide (GeAs), indium arsenide (InAs), and indium phosphide (InP). The second semiconductor chip 200 may include a conductive region, for example, an impurity-doped well or an impurity-doped structure. A semiconductor device layer including individual elements may be provided on the active surface of the second semiconductor chip 200. The individual elements may include, for example, transistors. The individual elements may include microelectronic devices such as image sensors, metal-oxide-semiconductor field effect transistors (MOSFET), system large scale integration (LSI), and CMOS imaging sensors (CIS), micro-electro-mechanical systems (MEMS), active devices, passive devices, etc.

The second semiconductor chip 200 may be a memory chip or a logic chip. The memory chip may be, for example, a volatile memory chip such as dynamic random access memory (DRAM) or static random access memory (SRAM), or may be a nonvolatile memory chip such as a phase-change random access memory (PRAM), a magnetoresistive random access memory (MRAM), ferroelectric random access memory (FeRAM), or resistive random access memory (RRAM). The logic chip may be a central processing unit (CPU) chip, a graphics processing unit (GPU) chip, an application processor (AP) chip, or an application specific integrated circuit (ASIC) chip.

In some embodiments, the first semiconductor chip 100 may be a logic chip including a logic element, and the second semiconductor chip 200 may be a memory chip. For example, the second semiconductor chip 200 may be a memory chip, and may be composed of a volatile memory chip and/or a nonvolatile memory chip. The first semiconductor chip 100 may be a logic chip and may be a central processing unit chip, a graphics processing unit chip, or an application processor chip. That is, the second semiconductor chip 200 and the first semiconductor chip 100 may perform different functions.

In some embodiments, the second semiconductor chip 200 may be arranged on the upper redistribution structure RDLb so that the active surface faces the upper redistribution structure RDLb. In this case, the second semiconductor chip 200 and the upper redistribution structure RDLb may be electrically connected to each other through an internal connection terminal CT2 formed between the second semiconductor chip 200 and the upper redistribution structure RDLb. That is, the second semiconductor chip 200 may be electrically connected to the lower redistribution structure RDLa through the internal connection terminal CT2, the upper redistribution structure RDLb, and the conductive posts 300.

In some embodiments, the second semiconductor chip 200 may be arranged on the upper redistribution structure RDLb so that the inactive surface faces the upper redistribution structure RDLb. The second semiconductor chip 200 may be electrically connected to the upper redistribution structure RDLb through a conductive wire (not shown).

A heat dissipation part (e.g., a heat sink) TE and a heat dissipation contact part (e.g., a heat dissipation contact) TE1 may be arranged on the top surface of the upper redistribution structure RDLb. In more detail, the heat dissipation contact part TE1 arranged on the top surface of the upper redistribution structure RDLb may be located on the top surfaces of a plurality of thermal vias TV1, TV3, and TV5 located at the uppermost end of the thermal vias TV arranged on the upper redistribution structure RDLb and respectively contacting the upper portions of a plurality of upper wiring layers RLb. The thermal vias TV may be formed of or include at least one of silver (Ag), copper (Cu), gold (Au), and aluminum (Al), or an alloy thereof, but is not limited thereto. In addition, some of the heat dissipation contact part TE1 may be arranged on the top surface of the second semiconductor chip 200 to be in contact with the second semiconductor chip 200. The heat dissipation part TE may be in contact with the plurality of heat dissipation contact part TE1 discussed above, may have a U shape as shown in FIG. 1, and may have a thickness as shown in the drawing, but is not limited thereto.

Heat generated by the first semiconductor chip 100 may be sequentially transferred along the plurality of thermal interface material layers TIM, the plurality of capacitor structures CAP, the plurality of thermal vias TV, the heat dissipation contact part TE1, and the heat dissipation part TE, and heat generated by the second semiconductor chip 200 may be sequentially transferred along the heat dissipation contact part TE1 and the heat dissipation part TE arranged on the top surface of the second semiconductor chip 200.

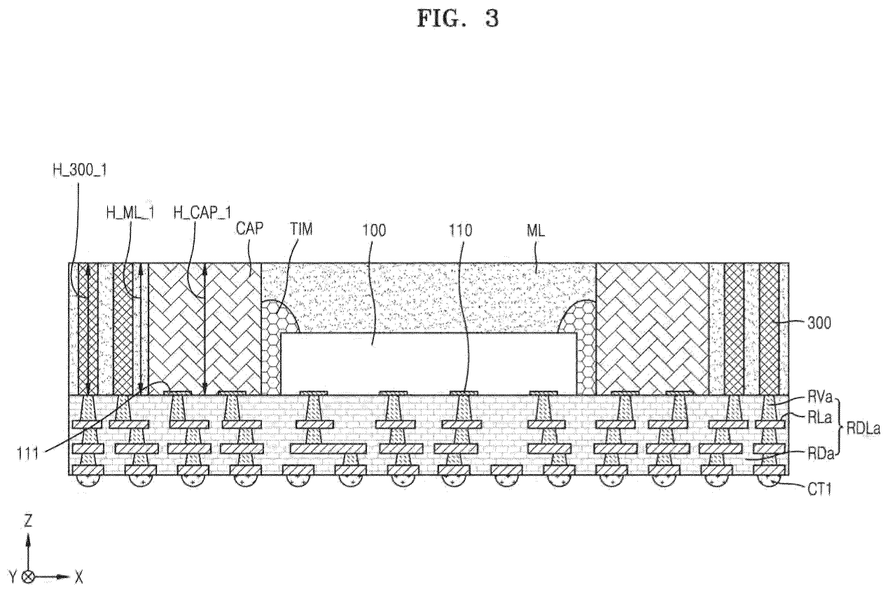

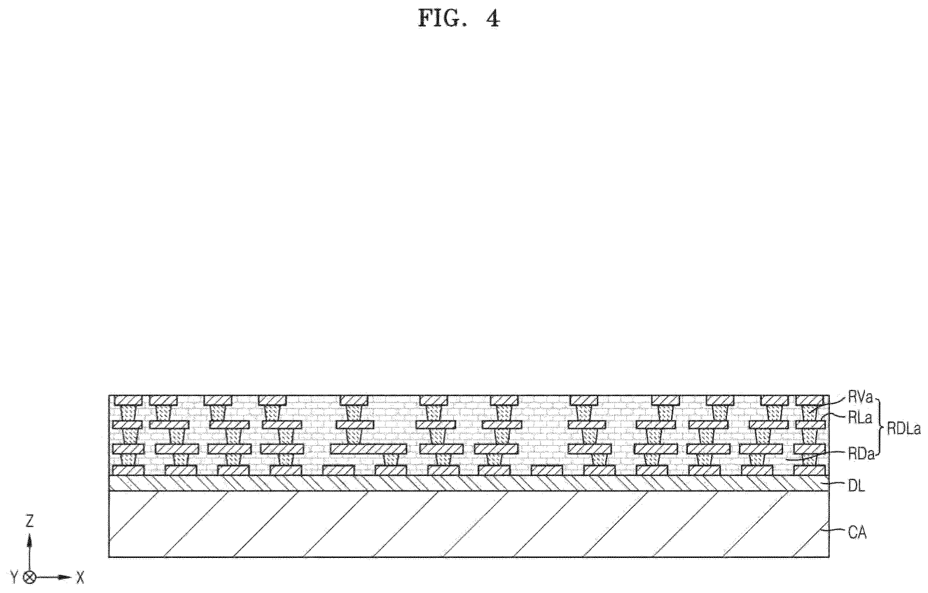

In some embodiments, the semiconductor package 1 may have a chip last structure in which the first semiconductor chip 100 is arranged on the top surface of the lower redistribution structure RDLa after the lower redistribution structure RDLa is formed on the carrier substrate CA of FIG. 4. However, the embodiments are not limited thereto, and the semiconductor package 1 may have a chip first structure as illustrated in FIG. 3. That is, the horizontal area of the lower vertical via RVa of the lower redistribution structure RDLa may vary with decreasing distance from the first semiconductor chip 100.

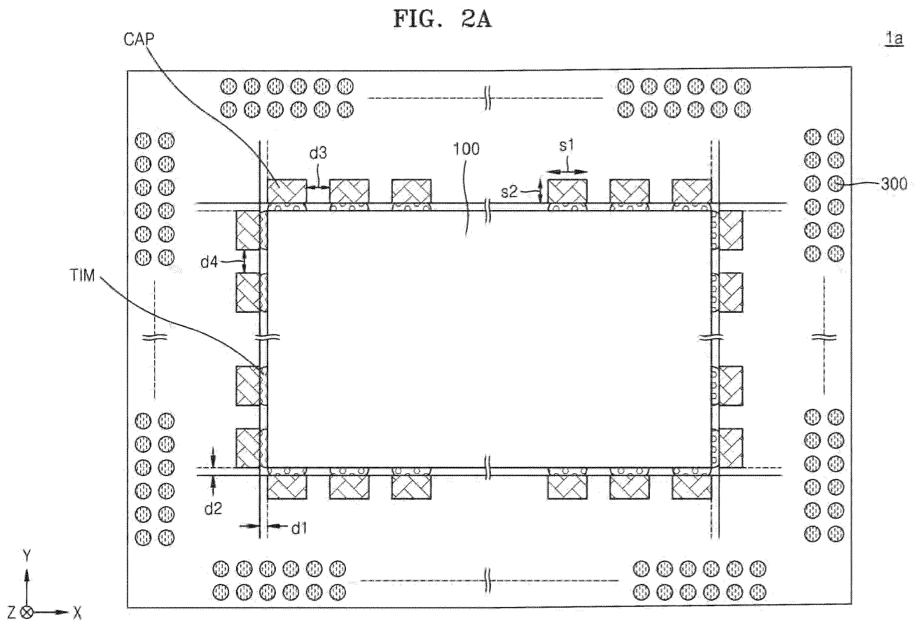

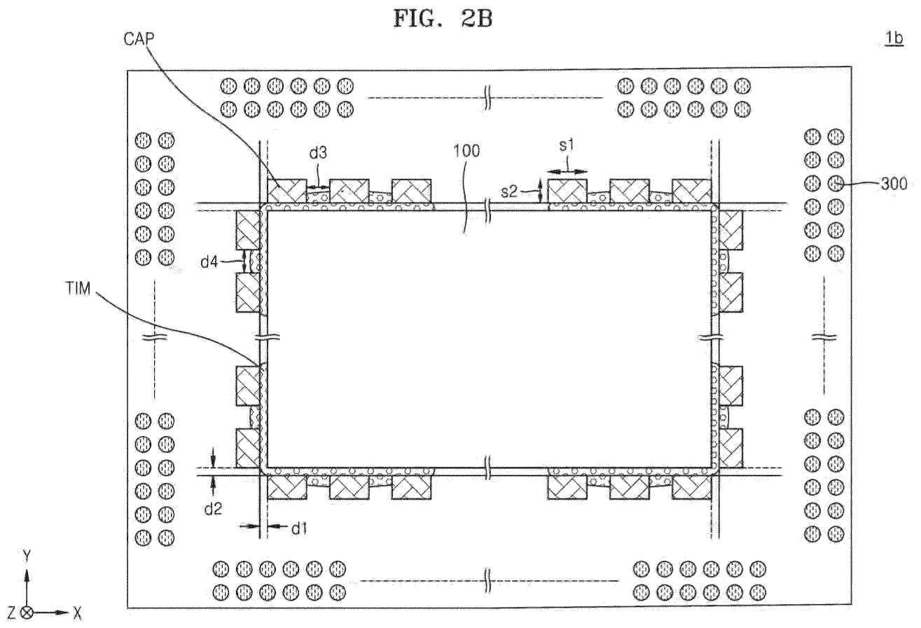

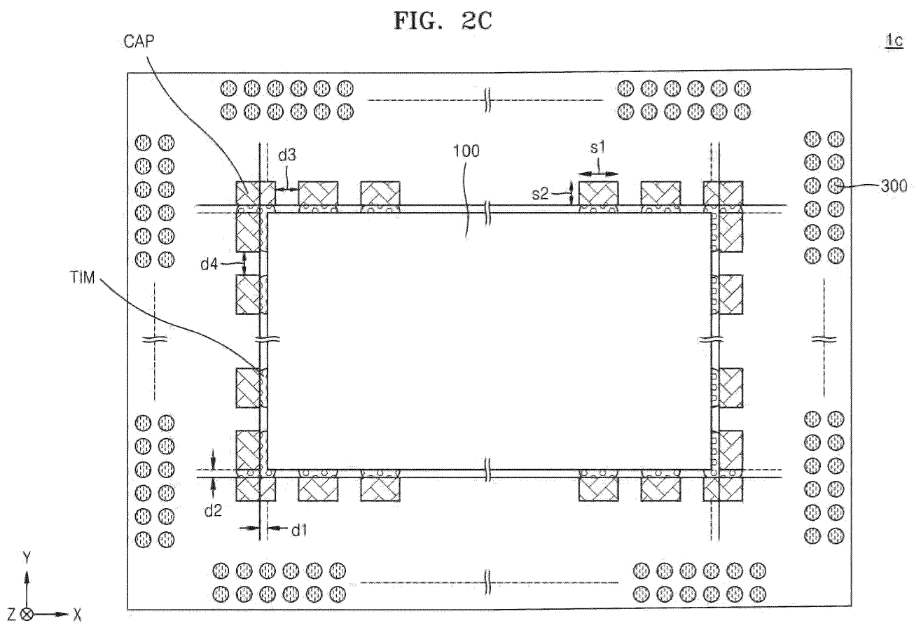

FIG. 2A is a schematic plan view of a semiconductor package according to an embodiment.

Referring to FIG. 2A, a semiconductor package 1a shows that one first semiconductor chip 100 is mounted on the top surface of the lower redistribution structure, but the number of first semiconductor chips 100 is not limited thereto, and two or more first semiconductor chips 100 may be mounted thereon. When two or more first semiconductor chips 100 are mounted on the lower redistribution structure, the first semiconductor chips 100 may be different types of chips. The plurality of conductive posts 300 may be spaced apart from each other at equal intervals in the first horizontal direction X or the second horizontal direction Y from the first semiconductor chip 100, and although two columns of the conductive posts are arranged in FIG. 2A, the number of conductive posts 300 is not limited thereto and the number of columns of conductive posts 300 is not limited thereto. In some embodiments, the conductive posts 300 each may have a column shape having a circular cross section. That is, the conductive posts 300 each may have a cylindrical shape, but the shape of the conductive posts 300 is not limited to those shown in the drawings.

The plurality of capacitor structures CAP may be arranged to be spaced apart from each other at equal intervals along edges of the first semiconductor chip 100 in a plan view in the first horizontal direction X or the second horizontal direction Y. A third spacing d3, which is a distance at which the plurality of capacitor structures CAP are spaced apart from each other in the first horizontal direction X, and a fourth spacing d4, which is a distance at which the plurality of capacitor structures CAP are spaced apart from each other in the second horizontal direction Y, may be equal to each other, but are not limited thereto. Furthermore, a first spacing d1, which is a distance at which the plurality of capacitor structures CAP are spaced apart from the first semiconductor chip 100 in a first horizontal direction X, and a second spacing d2, which is a distance at which the plurality of capacitor structures CAP are spaced apart from the first semiconductor chip 100 in a second horizontal direction Y, may be equal to each other for the first semiconductor chip 100, but are not limited thereto. The plurality of thermal interface material layers TIM may be arranged in each of the first spacing d1 and the second spacing d2, and the plurality of thermal interface material layers TIM may respectively connect the plurality of capacitor structures CAP with the first semiconductor chip 100, but the number of connections is not limited thereto. The number of the plurality of capacitor structures in FIG. 2A is not limited to the number illustrated in the drawings. A first length s1, which is a length of a first side of the capacitor structure CAP, may be greater than a second length s2, which is a length of a second side of the capacitor structure CAP, but is not limited thereto. The positions of both ends of the first semiconductor chip 100 in the first horizontal direction X (e.g., edges of the first semiconductor chip 100 extending in the second horizontal direction Y) may coincide with the positions of both ends of the plurality of capacitor structures CAP located at both ends among the plurality of capacitor structures CAP arranged in the first horizontal direction X (e.g., outermost edges of the plurality of capacitors CAP located at the ends of the first semiconductor chip 100 in the first horizontal direction X). In addition, the positions of both ends of the first semiconductor chip 100 in the second horizontal direction Y (e.g., edges of the first semiconductor chip 100 extending in the first horizontal direction X) may coincide with the positions of both ends of the plurality of capacitor structures CAP located at both ends among the plurality of capacitor structures CAP arranged in the second horizontal direction Y (e.g., outermost edges of the plurality of capacitors CAP located at the ends of the first semiconductor chip 100 in the second horizontal direction Y). In other words, a length of an edge (e.g., a first edge) of the first semiconductor chip 100 in the first horizontal direction X may be the same as a distance between opposite side surfaces of a pair of capacitor structures CAP arranged at both ends in the first horizontal direction X among the plurality of capacitor structures CAP. A length of an edge (e.g., a second edge) of the first semiconductor chip 100 in the second horizontal direction Y may be the same as a distance between opposite side surfaces of a pair of capacitor structures CAP arranged at both ends in the second horizontal direction Y among the plurality of capacitor structures CAP.

For example, the plurality of capacitors CAP may include a first capacitor at an end of the first edge of the first semiconductor chip 100 in the first horizontal direction X and a second capacitor at an opposite end of the first edge of the first semiconductor chip 100 in the first horizontal direction X. The length of the first edge of the first semiconductor chip 100 in the first horizontal direction X may be the same as the distance between opposite side surfaces of the first capacitor and the second capacitor.

For example, the plurality of capacitors CAP may include a third capacitor at an end of the second edge of the first semiconductor chip 100 in the second horizontal direction Y and a fourth capacitor at an opposite end of the second edge of the first semiconductor chip 100 in the second horizontal direction Y. The length of the second edge of the first semiconductor chip 100 in the second horizontal direction Y may be the same as the distance between opposite side surfaces of the third capacitor and the fourth capacitor.

FIG. 2B is a plan view schematically illustrating a semiconductor package according to another embodiment. Hereinafter, for convenience of explanation, differences from FIG. 2A will be described in detail.

A semiconductor package 1b shows that one first semiconductor chip 100 is mounted on the top surface of the lower redistribution structure, but the number of first semiconductor chips 100 is not limited thereto, and two or more first semiconductor chips 100 may be mounted thereon. When two or more first semiconductor chips 100 are mounted on the lower redistribution structure, the first semiconductor chips 100 may be different types of chips. The plurality of thermal interface material layers TIM may be arranged in the first spacing d1 and the second spacing d2 between the first semiconductor chip 100 and the plurality of capacitor structures CAP. The thermal interface material layers TIM may be in contact with at least two capacitor structures CAP and the first semiconductor chip 100 at the same time. As shown in FIGS. 2A and 2B, the plurality of thermal interface material layers TIM may be formed to surround at least a portion of edges of the first semiconductor chip 100 in the first horizontal direction X or the second horizontal direction Y, but a surrounding area is not limited to that shown in the drawings. In addition, the thermal interface material layer TIM may be also arranged in the third spacing d3, which is the spacing in the first horizontal direction X or the fourth spacing d4, which is the spacing in the second horizontal direction Y, between adjacent capacitors of the plurality of capacitor structures CAP, in FIG. 2B unlike those shown in FIG. 2A. The plurality of thermal interface material layers TIM arranged among the plurality of capacitor structures CAP may not only connect the plurality of capacitor structures CAPs with the first semiconductor chip 100, but may also connect one capacitor structure CAP with another capacitor structure CAP adjacent to the one capacitor structure CAP. Therefore, it is possible to efficiently conduct heat through the connection between the components described above, and heat dissipation characteristics may thereby be further improved.

FIG. 2C is a plan view schematically illustrating a semiconductor package according to another embodiment. Hereinafter, for convenience of explanation, differences from FIGS. 2A and 2B will be described in detail.

A semiconductor package 1c shows that one first semiconductor chip 100 is mounted on the top surface of the lower redistribution structure, but the number of first semiconductor chips 100 is not limited thereto, and two or more first semiconductor chips 100 may be mounted thereon. Among the plurality of capacitor structures CAP, a plurality of capacitor structures CAP arranged at the outermost side from the center of the first semiconductor chip 100 in the first horizontal direction X or the second horizontal direction Y have respective extension lines from an outermost edge of each capacitor structure which may be matched, and each of the matching extension lines may extend in the same direction. For example, an extension line extending in the second horizontal direction Y based on one edge located at an outermost side from the center of the first semiconductor chip 100, from among four edges of one capacitor structure CAP located at the rightmost side in the first horizontal direction X and at the uppermost side in the second horizontal direction Y, from among the plurality of capacitor structures CAP of FIG. 2C, may match an extension line extending in the second horizontal direction Y based on one edge located at an outermost side from the center of the first semiconductor chip 100, from among four edges of one capacitor structure CAP located at the rightmost side in the first horizontal direction X and at the lowermost side in the second horizontal direction Y, from among the plurality of capacitor structures CAP.

For example, in plan view, a capacitor at each corner of the first semiconductor chip 100 may extend beyond an edge of the first semiconductor chip 100 in the first horizontal direction X or in the second horizontal direction Y. Capacitors located at neighboring corners may extend beyond the edge of the first semiconductor chip 100 to the same extent as each other as shown, e.g., in FIG. 2C.

In addition, an extension line extending in the first horizontal direction X based on one edge located at an outermost side from the center of the first semiconductor chip 100, from among four edges of one capacitor structure CAP located at the rightmost side in the first horizontal direction X and at the uppermost side in the second horizontal direction Y, from among the plurality of capacitor structures CAP, may match an extension line extending in the first horizontal direction X based on one edge located at an outermost side from the center of the first semiconductor chip 100, from among four edges of one capacitor structure CAP located at the leftmost side in the first horizontal direction X and at the uppermost side in the second horizontal direction Y, from among the plurality of capacitor structures CAP.

In other words, the outermost edges of the four capacitor structures CAP at the outermost side from the center of the first semiconductor chip 100 may be entirely connected in one rectangular shape.

FIG. 3 is a cross-sectional view schematically illustrating a semiconductor package according to another embodiment. Most elements constituting the semiconductor package described below and materials constituting the components are substantially the same as or similar to those described with reference to FIGS. 1 and 2A. Therefore, for convenience of explanation, the structure of FIG. 3 will be described focusing on the differences from the semiconductor package 1 of FIG. 1 described above.

Referring to FIG. 3, a semiconductor package may have a chip first structure. Specifically, the semiconductor package may have a structure in which the first semiconductor chip 100 is mounted on the carrier substrate CA in FIG. 4 and then the lower redistribution structure RDLa is formed on the first semiconductor chip 100.

The lower redistribution structure RDLa of the semiconductor package may include a lower wiring layer R1a, a lower vertical via Rva vertically connecting different portions of the lower wiring layer R1a to each other, and a lower insulating layer Rda surrounding the lower wiring layer R1a and the lower vertical via Rva.

In some embodiments, the lower vertical via Rva structurally arranged inside the lower redistribution structure RDLa may be formed such that the width in the first horizontal direction X and/or the width in the second horizontal direction Y gradually decrease as it approaches the bottom surface of the first semiconductor chip 100. That is, the horizontal area of the lower vertical via Rva of the lower redistribution structure RDLa may decrease with decreasing distance from the first semiconductor chip 100.

The first semiconductor chip 100 of the semiconductor package may be positioned on the lower redistribution structure RDLa. Each of the semiconductor chip pads 110 and the connection pads 111 located at the active surface of the first semiconductor chip 100 and at places where the plurality of capacitor structures CAP are in contact with the lower redistribution structure RDLa may be in contact with the lower redistribution structure RDLa.

For example, levels H_300_1 of the top surfaces in the vertical direction Z of the plurality of conductive posts 300 may be the same as levels H_ML_1 of the top surfaces in the vertical direction Z of the molding layer ML and levels H_CAP_1 of the top surfaces in the vertical direction Z of the plurality of capacitor structures CAP.

The top surfaces of the plurality of conductive posts 300, the top surface of the molding layer ML, and the top surfaces of the plurality of capacitor structures CAP may be coplanar. In some embodiments, the top surface of the first semiconductor chip 100, the top surfaces of the plurality of conductive posts 300, and the top surface of the molding layer ML may be coplanar. For example, the plurality of conductive posts 300 and/or the plurality of capacitors CAP may completely penetrate the molding layer ML.

FIGS. 4 to 15 are cross-sectional views illustrating a method of manufacturing a semiconductor package according to a process sequence, according to an embodiment.

Referring to FIG. 4, an adhesive insulating layer DL may be attached to a carrier CA, and a lower re-wiring structure R1a may be formed on the adhesive insulating layer DL.

The carrier CA may be formed of or include, for example, glass, semiconductor, ceramic, plastic, or aluminum oxide. The adhesive insulating layer DL may include any material capable of fixing the lower redistribution structure RDLa. The adhesive insulating layer DL may be, for example, an adhesive tape in which an adhesive force is weakened by heat treatment or an adhesive force is weakened by laser irradiation. In some embodiments, the lower redistribution structure RDLa may be formed on the adhesive insulating layer DL through a plating process or a deposition process.

The lower redistribution structure RDLa may include the lower wiring layer R1a, the lower vertical via Rva vertically connecting different portions of the lower wiring layer R1a to each other, and the lower insulating layer Rda surrounding the lower wiring layer R1a and the lower vertical via Rva.

As shown in FIGS. 4 to 15, according to a method of manufacturing a semiconductor package having a chip last structure, a horizontal width of the lower vertical via Rva may increase in a direction away from the carrier CA. For example, the lower wiring layer R1a and the lower vertical via Rva in contact with the bottom surface of the lower wiring layer R1a may be formed together to form an integral body. However, the embodiments are not limited thereto, and according to a method of manufacturing a semiconductor package having a chip last structure, the horizontal width of the lower vertical via Rva may decrease in a direction away from the carrier CA.

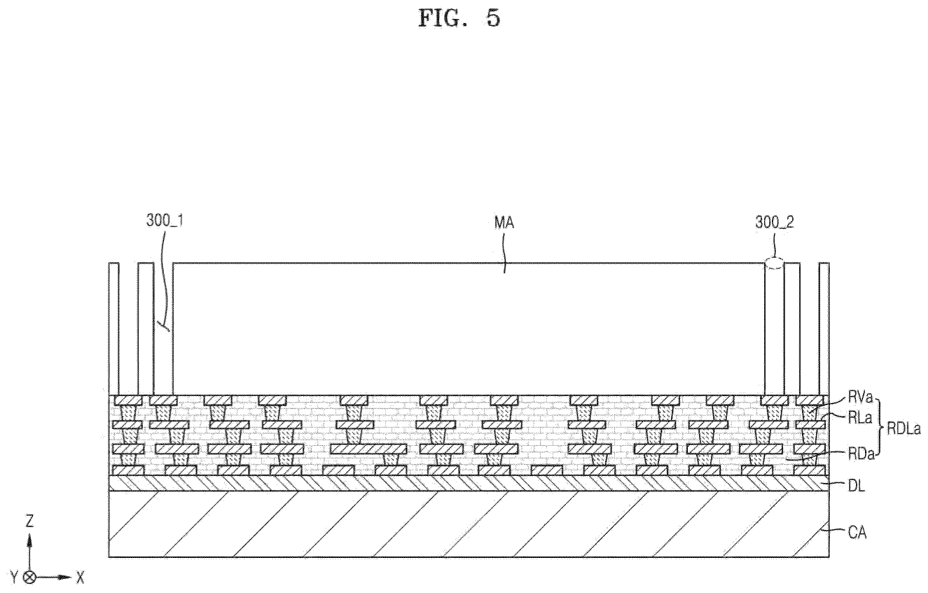

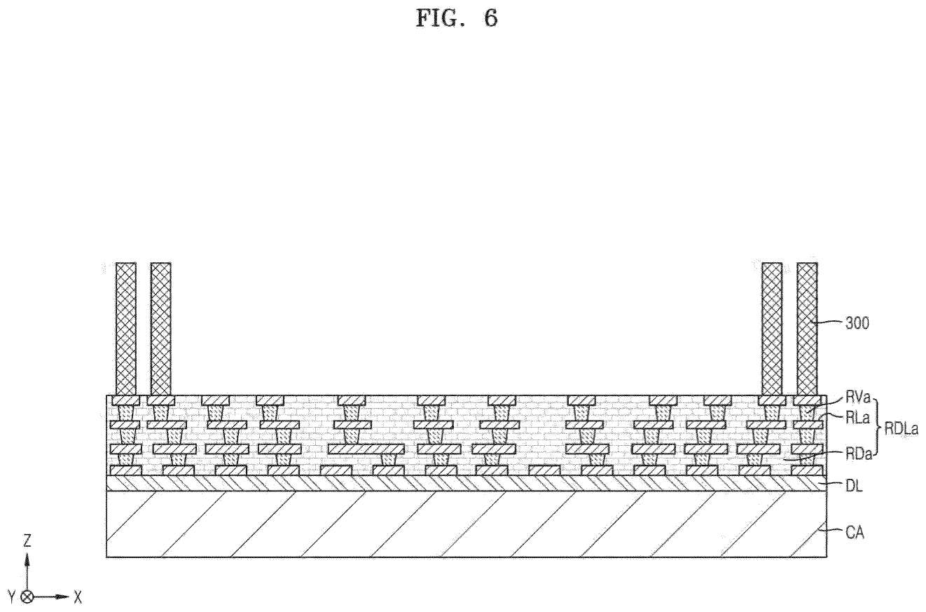

Referring to FIGS. 5 and 6, the conductive posts 300 may be formed on the lower redistribution structure RDLa. A mask MA may be formed as a sacrificial insulating layer on the lower redistribution structure RDLa, and a plurality of vias penetrating the mask MA may be formed. The plurality of vias may include a conductive post generation space 300_1, which is a space in which the conductive post is to be generated, and a plating process region 300_2, which is positioned above the conductive post generation space 300_1 and into which a plating material is to be inserted. The horizontal width of the conductive post generation space 300_1 may be constant, but the embodiments are not limited thereto. The horizontal width of the conductive post generation space 300_1 may decrease with decreasing distance from the lower redistribution structure RDLa.

Next, through a plating process, the plating process region 300_2 may be filled with a conductive material to form the plurality of conductive posts 300, to fit the shape of the conductive post generating space 300_1. The conductive posts 300 may be in contact with and electrically connected to the lower redistribution structure RDLa.

In some embodiments, since the conductive post generation space 300_1 completely penetrates the mask A, which is the sacrificial insulating layer, the heights of the plurality of conductive posts 300 in the vertical direction Z may be the same. For example, the top surfaces of the conductive posts 300 may be coplanar.

After forming the plurality of conductive posts 300, the mask MA as the sacrificial insulating layer may be removed.

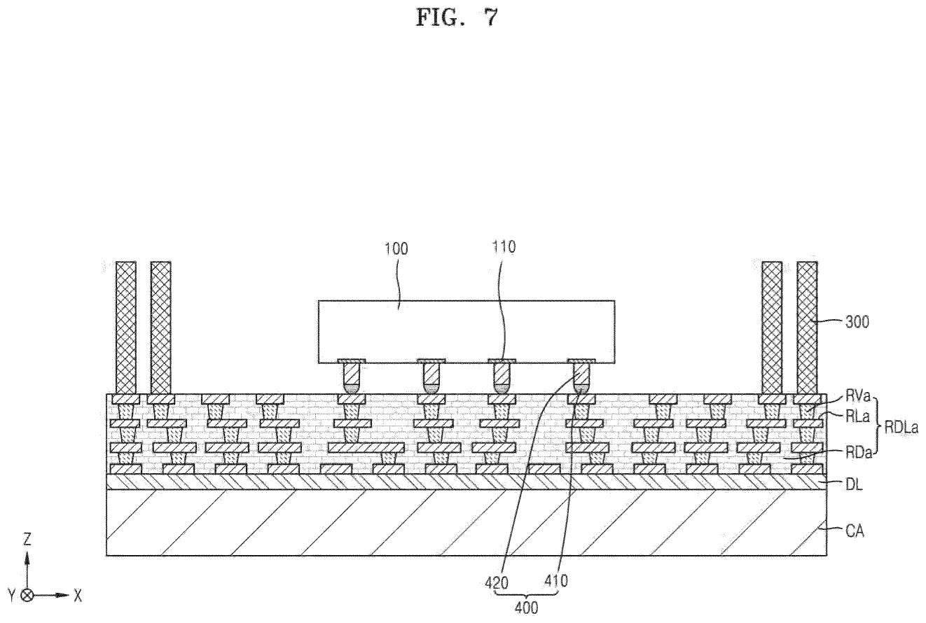

Referring to FIG. 7, the first semiconductor chip 100 may be attached to a central region of the lower redistribution structure RDLa. In some embodiments, the first semiconductor chip 100 may be electrically connected to the lower redistribution structure RDLa via chip connection terminals 400 that are connected to semiconductor chip pads 110 formed on the active surface of the first semiconductor chip 100. More specifically, a conductive cap 420 is in contact with the bottom surface of the semiconductor chip pad 110, and a lower pillar 410 is located between the conductive cap 420 and the lower redistribution structure RDLa. Accordingly, the first semiconductor chip 100 may be electrically connected to the lower redistribution structure RDLa.

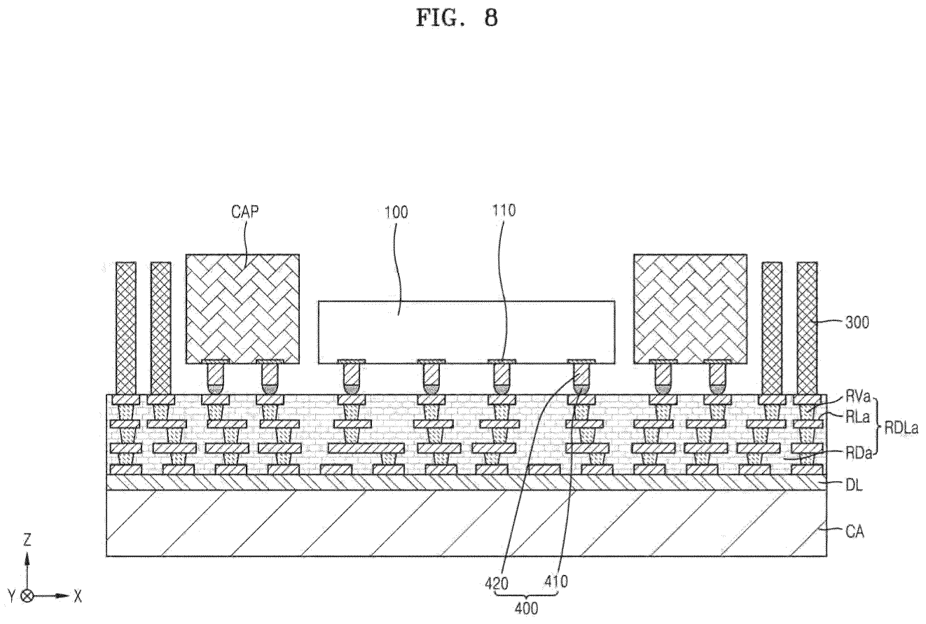

Referring to FIG. 8, a plurality of capacitor structures CAP may be attached between the conductive post 300 and the first semiconductor chip 100 on the top surface of the lower redistribution structure RDLa. In some embodiments, the plurality of capacitor structures CAP may be electrically connected to the lower redistribution structure RDLa via chip connection terminals 400 that are connected to connection pads 111 formed on the plurality of capacitor structures CAP. More specifically, the conductive cap 420 is in contact with the bottom surface of the connection pad 111, and the lower pillar 410 is located between the conductive cap 420 and the lower redistribution structure RDLa. Accordingly, the plurality of capacitor structures CAP may be electrically connected to the lower redistribution structure RDLa. Components of the chip connection terminals 400 connected to the bottom surface of the first semiconductor chip 100 and the chip connection terminals 400 connected to the bottom surface of the plurality of capacitor structures CAP, the semiconductor chip pads 110, and the connection pads 111 are shown in the same manner, but the sizes, shapes, and the like are not limited thereto.

Referring to FIGS. 7 and 8, the first semiconductor chip 100 and the plurality of capacitor structures CAP may be sequentially attached to the upper portion of the lower redistribution structure RDLa. However, the first semiconductor chip 100 and the plurality of capacitor structures CAP may be simultaneously mounted through a flip chip mount process.

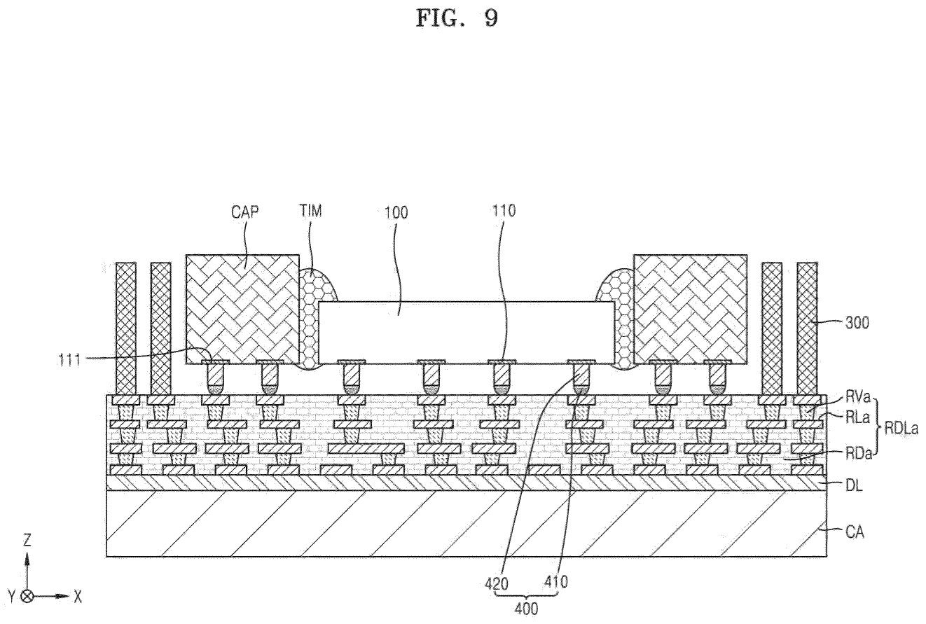

Referring to FIG. 9, a plurality of thermal interface material layers TIM may be arranged between the first semiconductor chip 100 and the plurality of capacitor structures CAP. In one embodiment, the plurality of thermal interface material layers TIM may be formed to surround at least a portion of edges of the first semiconductor chip 100 in a horizontal direction. As shown, an uppermost end and a lowermost end of the thermal interface material layer TIM may be formed to be equal to or greater than the top and bottom surfaces of the first semiconductor chip 100 in the vertical direction, respectively. For example, an uppermost end of each of the plurality of thermal interface layers TIM may be on a same plane as or above the top surface of the first semiconductor chip 100 in a vertical direction, and a lowermost end of each of the plurality of thermal interface material layers TIM may be on a same plane as or below the bottom surface of the semiconductor chip in the vertical direction. The thicknesses and shapes of the thermal interface material layers TIM are not limited to those shown in the drawings.

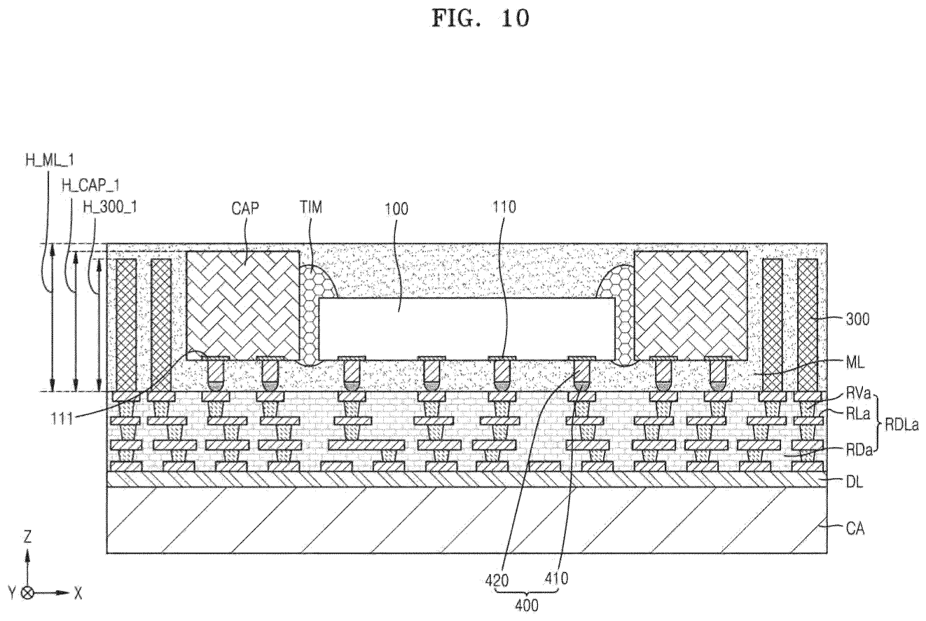

Referring to FIG. 10, a molding layer ML may be formed to surround the first semiconductor chip 100, the plurality of conductive posts 300, and the plurality of capacitor structures CAP.

In some embodiments, the molding layer ML may be formed to be thick so that the molding layer ML covers upper portions of the first semiconductor chip 100, the plurality of conductive posts 300, and the plurality of capacitor structures CAP. Therefore, the level H_ML_1 of the top surface of the molding layer ML in the vertical direction Z may be formed higher than the level H_300_1 of the top surface of the plurality of conductive posts 300 in the vertical direction Z and the level H_CAP_1 of the top surface of the plurality of capacitor structures CAP in the vertical direction Z.

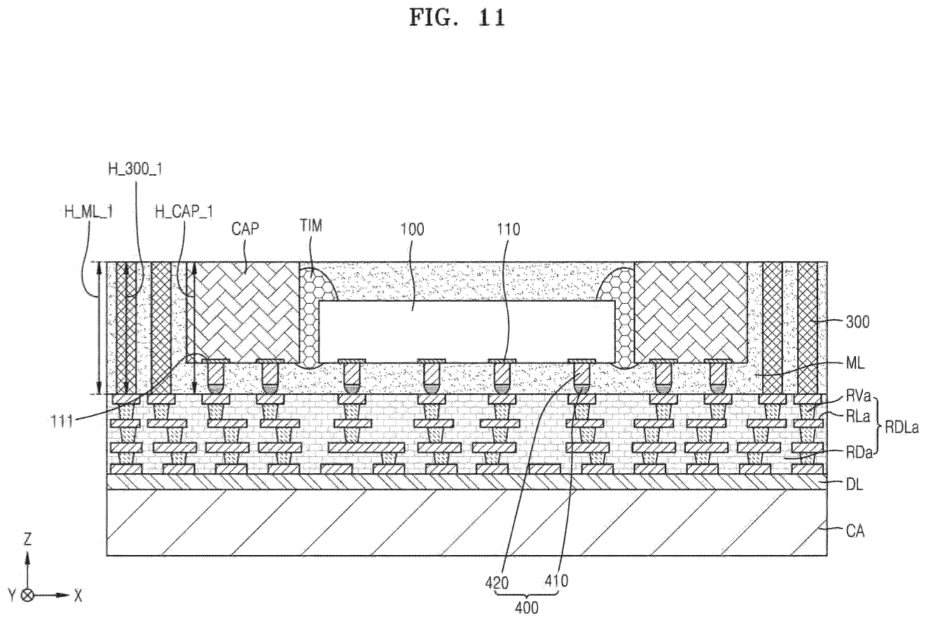

Referring to FIG. 11, after the molding layer ML is formed, upper portions of each configuration of the plurality of conductive posts 300 and the plurality of capacitor structures CAP may be removed through a grinder such that top surfaces of the plurality of conductive posts 300 and the plurality of capacitor structures CAP are exposed to the outside.

In some embodiments, the top surface of the molding layer ML, the top surfaces of the conductive posts 300, and the top surfaces of the plurality of capacitor structures CAP may be coplanar.

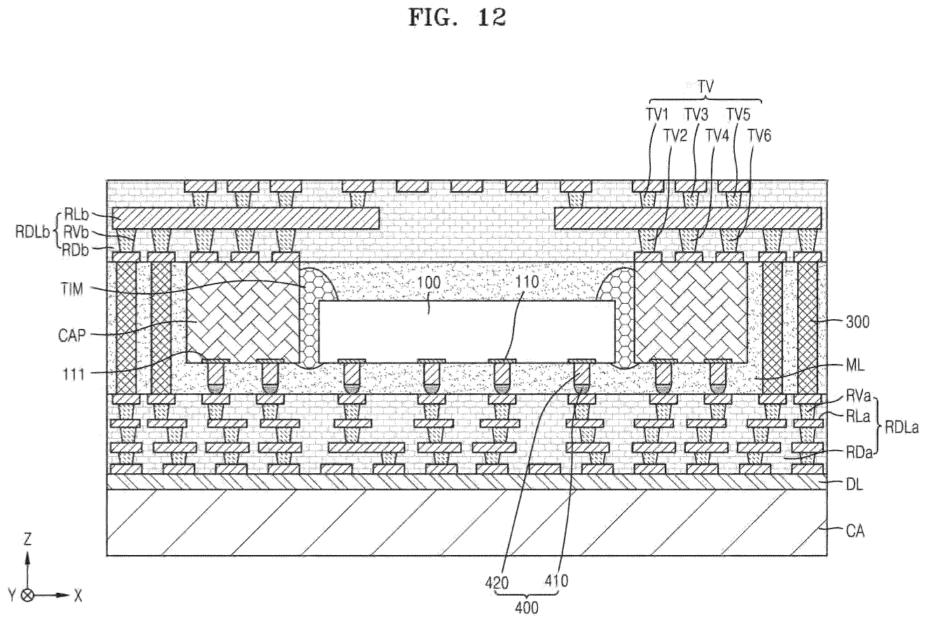

Referring to FIG. 12, an upper redistribution structure RDLb may be formed on the molding layer ML, the conductive posts 300, and the capacitor structures CAP.

The top surfaces of the conductive posts 300 may be in contact with the upper redistribution structure RDLb. For example, the conductive posts 300 may be electrically connected to the upper redistribution structure RDLb. Accordingly, the upper redistribution structure RDLb may be electrically connected to the lower redistribution structure RDLa through the conductive posts 300. The plurality of conductive posts 300 may be spaced apart from the upper redistribution structure RDLb in the vertical direction Z with the molding layer ML therebetween. The plurality of capacitor structures CAP may be connected to the upper redistribution structure RDLb. In more detail, the upper wiring layer RLb in which the plurality of capacitor structures CAP are connected to the upper redistribution structure RDLb may be connected to the plurality of thermal vias TV. Two layers of thermal vias TV in the vertical direction Z with the first to sixth thermal vias TV1, TV2, TV3, TV4, TV5, and TV6 are shown in the drawings, but the number and shape thereof are not limited to those shown in the drawings. In addition, in the drawings, both the upper vertical via RVb and the plurality of thermal vias TV are shown to be connected to the same upper wiring layer RLb, but the embodiments are not necessarily limited thereto, and each of the upper vertical via RVb and the thermal via TV may be connected to different upper wiring layers RLb. The thermal vias TV may be formed of or include at least one metal of silver (Ag), copper (Cu), gold (Au), and aluminum (Al), or an alloy thereof, but the embodiments are not limited thereto, and the thermal vias may be formed of a material having high thermal conductivity.

The upper redistribution structure RDLb may include an upper wiring layer RLb, an upper vertical via RVb vertically connecting the upper wiring layer RLb to other elements such as the plurality of conductive posts 300, a thermal via TV, and an upper insulating layer RDb surrounding peripheral portions of the upper wiring layer RLb, the upper vertical via RVb and the thermal via TV.

Here, according to the formation process of the upper vertical via RVb and the thermal via TV, structurally, the upper vertical via RVb and the thermal via TV arranged inside the upper redistribution structure RDLb may be formed so that the horizontal areas of the upper vertical via RVb and the thermal via TV decrease as they approach the first semiconductor chip 100.

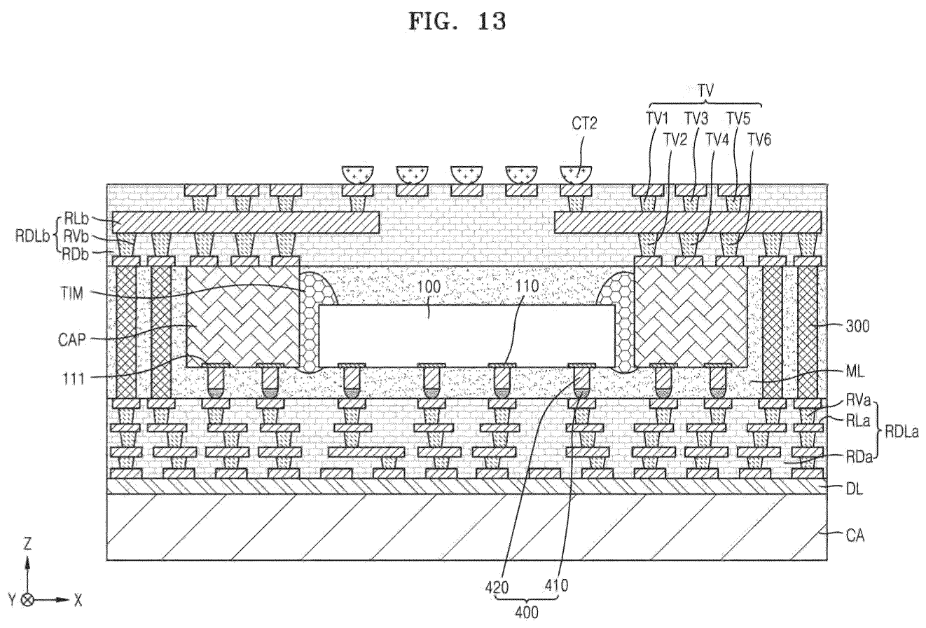

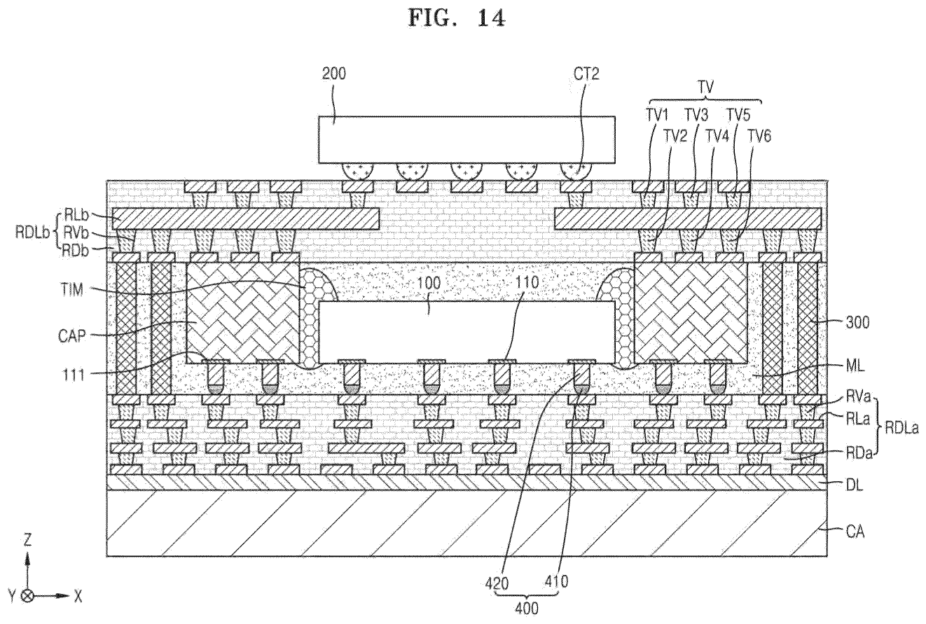

Referring to FIGS. 13 and 14, an internal connection terminal CT2 may be arranged on the upper redistribution structure RDLb, and a second semiconductor chip 200 may be arranged on the internal connection terminal CT2.

The second semiconductor chip 200 may be arranged on the upper redistribution structure RDLb so that the active surface faces the upper redistribution structure RDLb. In this case, the second semiconductor chip 200 and the upper redistribution structure RDLb may be electrically connected to each other through an internal connection terminal CT2 formed between the second semiconductor chip 200 and the upper redistribution structure RDLb.

The second semiconductor chip 200 may be electrically connected to the lower redistribution structure RDLa through the internal connection terminal CT2, the upper redistribution structure RDLb, and the conductive posts 300. However, a method of arranging the second semiconductor chip 200 on the upper redistribution structure RDLb is not limited thereto.

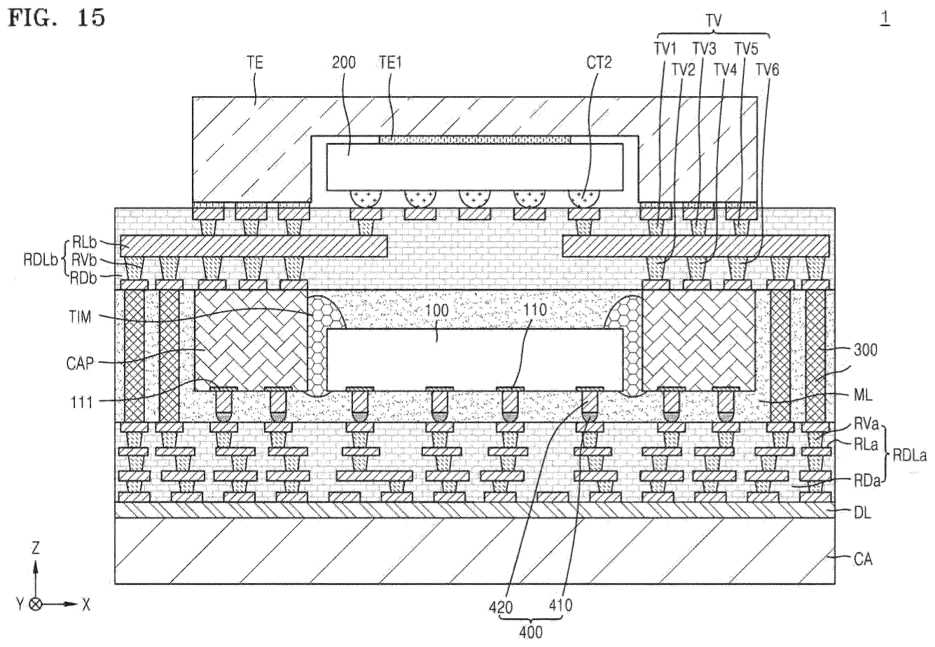

Referring to FIG. 15, the heat dissipation contact part TE1 may be arranged on the top surface of the upper redistribution structure RDLb, and the heat dissipation part TE may be arranged on the top surface of the heat dissipation contact part TE1. In more detail, the heat dissipation contact part TE1 may be arranged not only on the top surface of the upper redistribution structure RDLb but also on the top surface of the second semiconductor chip 200, thereby forming a path through which heat generated from the second semiconductor chip 200 as well as heat generated from the first semiconductor chip 100 is conducted.

Referring to FIGS. 1 and 15, the carrier CA and the adhesive insulating layer DL may be removed in FIG. 15, and an external connection terminal CT1 may be formed on the bottom surface of the lower redistribution structure RDLa, the result of which may be the same as the shape of the semiconductor package 1 shown in FIG. 1.

While the inventive concept has been particularly shown and described with reference to embodiments thereof, it will be understood that various changes in form and details may be made therein without departing from the spirit and scope of the disclosure.

What is claimed is:

1. A semiconductor package comprising:
a lower redistribution structure;
a semiconductor chip on a top surface of the lower redistribution structure;
a plurality of conductive posts on a top surface of the lower redistribution structure and spaced apart from the semiconductor chip in a direction parallel to the top surface of the lower redistribution structure;
a plurality of capacitors on the top surface of the lower redistribution structure, the plurality of capacitors being between the semiconductor chip and the plurality of conductive posts; and
a plurality of thermal interface material layers between the semiconductor chip and the plurality of capacitors.

2. The semiconductor package of claim 1, further comprising:
an upper redistribution structure on the conductive posts; and
a plurality of thermal vias in the upper redistribution structure, the plurality of thermal vias being connected to the plurality of capacitors.

3. The semiconductor package of claim 2, further comprising:
a heat dissipation contact on a top surface of the upper redistribution structure; and
a heat sink on a top surface of the heat dissipation contact.

4. The semiconductor package of claim 1, further comprising a molding layer covering the top surface of the lower redistribution structure, the molding layer surrounding the semiconductor chip, the plurality of conductive posts, the plurality of capacitors, and the plurality of thermal interface material layers.

5. The semiconductor package of claim 1, further comprising a plurality of chip connection terminals between the lower redistribution structure and the semiconductor chip and between the lower redistribution structure and the plurality of capacitors.

6. The semiconductor package of claim 5, wherein the plurality of chip connection terminals each include: a lower pillar electrically connected to the lower redistribution structure; and a conductive cap between the lower pillar and the semiconductor chip to electrically connect the semiconductor chip to the lower pillar.

7. The semiconductor package of claim 1, wherein the plurality of capacitors are spaced apart from each other at equal intervals along a first edge of the semiconductor chip in a plan view.

8. The semiconductor package of claim 7, wherein a first capacitor of the plurality of capacitors is at an end of the first edge of the semiconductor chip in a first horizontal direction and a second capacitor is at an opposite end of the first edge of the semiconductor chip in the first horizontal direction,
a length of the first edge of the semiconductor chip in the first horizontal direction is the same as a distance between opposite side surfaces of the first capacitor and the second capacitor,
a third capacitor of the plurality of capacitors is at an end of a second edge of the semiconductor chip in a second horizontal direction and a fourth capacitor is at an opposite end of the second edge of the semiconductor chip in the second horizontal direction, and
a length of the second edge of the semiconductor chip in the second horizontal direction is the same as a distance between opposite side surfaces of the third capacitor and the fourth capacitor.

9. The semiconductor package of claim 7, wherein at least one of the plurality of thermal interface material layers is in contact with the semiconductor chip and with at least two capacitors from among the plurality of capacitor structures.

10. The semiconductor package of claim 1, further comprising a plurality of external connection terminals on a bottom surface of the lower redistribution structure.

11. A semiconductor package comprising:
a lower redistribution structure;
a semiconductor chip on a top surface of the lower redistribution structure;
a plurality of conductive posts on the top surface of the lower redistribution structure and spaced apart from the semiconductor chip in a direction parallel to the top surface of the lower redistribution structure;
a plurality of capacitors on the top surface of the lower redistribution structure, the plurality of capacitors being between the semiconductor chip and the plurality of conductive posts;
a plurality of thermal interface material layers between the semiconductor chip and the plurality of capacitors;
an upper redistribution structure on the conductive posts; and
a plurality of thermal vias in the upper redistribution structure and connected to the plurality of capacitors, wherein
an area of the semiconductor chip in a plan view is smaller than an area of the lower redistribution structure in the plan view.

12. The semiconductor package of claim 11, further comprising
a heat dissipation contact on a top surface of the upper redistribution structure, and
a heat dissipation part on a top surface of the heat dissipation contact.

13. The semiconductor package of claim 11, wherein an uppermost end of each of the plurality of thermal interface material layers is on a same plane as or above a top surface of the semiconductor chip in a vertical direction, and
a lowermost end of each of the plurality of thermal interface material layers is on a same plane as or below a bottom surface of the semiconductor chip in the vertical direction.

14. The semiconductor package of claim 11, wherein at least one of the plurality of thermal interface material layers is in contact with at least two of the plurality of capacitors and the semiconductor chip

15. The semiconductor package of claim 11, further comprising a molding layer covering the top surface of the lower redistribution structure, the molding layer surrounding the semiconductor chip, the plurality of conductive posts, the plurality of capacitors, and the plurality of thermal interface material layers.

16. The semiconductor package of claim 11, further comprising a plurality of chip connection terminals between the lower redistribution structure and the semiconductor chip and between the lower redistribution structure and the plurality of capacitors.

17. The semiconductor package of claim 16, wherein the plurality of chip connection terminals each include: a lower pillar electrically connected to the lower redistribution structure; and a conductive cap between the lower pillar and the semiconductor chip to electrically connect the semiconductor chip to the lower pillar.

18. The semiconductor package of claim 11, wherein
the plurality of capacitors are spaced apart from each other at equal intervals along a first edge of the semiconductor chip in a plan view, a first capacitor of the plurality of capacitors is at an end of the first edge of the semiconductor chip in a first horizontal direction and a second capacitor is at an opposite end of the first edge of the semiconductor chip in the first horizontal direction,
a length of the first edge of the semiconductor chip in a first horizontal direction is the same as a distance between opposite side surfaces of the first capacitor and the second capacitor,
a third capacitor of the plurality of capacitors is at an end of a second edge of the semiconductor chip in a second horizontal direction and a fourth capacitor is at an opposite end of the second edge of the semiconductor chip in the second horizontal direction, and
a length of the second edge of the semiconductor chip in the second horizontal direction is the same as a distance between opposite side surfaces of the third capacitor and the fourth capacitor.

19. A semiconductor package comprising:
a lower redistribution structure;
a semiconductor chip on a top surface of the lower redistribution structure;
a plurality of conductive posts on a top surface of the lower redistribution structure and spaced apart from the semiconductor chip in a first horizontal direction parallel to the top surface of the lower redistribution structure or in a second horizontal direction perpendicular to the first horizontal direction;
a plurality of capacitors on the top surface of the lower redistribution structure, the plurality of capacitors being between the semiconductor chip and the plurality of conductive posts;
a plurality of thermal interface material layers between the semiconductor chip and the plurality of capacitors;
a plurality of chip connection terminals between the lower redistribution structure and the semiconductor chip and between the lower redistribution structure and the plurality of capacitors;
a molding layer covering the top surface of the lower redistribution structure, the molding layer surrounding the semiconductor chip, the plurality of conductive posts, the plurality of capacitors, the plurality of thermal interface material layers, and the plurality of chip connection terminals;
an upper redistribution structure on the conductive posts;
a plurality of thermal vias in the upper redistribution structure, the plurality of thermal vias being connected to the plurality of capacitors,
a heat dissipation contact on a top surface of the upper redistribution structure; and
a heat dissipation part on a top surface of the heat dissipation contact, wherein
heat generated from the semiconductor chip is transferred sequentially along the plurality of thermal interface material layers, the plurality of capacitors, the plurality of thermal vias, the heat dissipation contact, and the heat dissipation part,
an area of the semiconductor chip in a plan view is smaller than an area of the lower redistribution structure in the plan view,
the plurality of thermal interface material layers surround at least part of horizontal edges of the semiconductor chip,
an uppermost end of each of the plurality of thermal interface material layers is on a same plane as or above a top surface of the semiconductor chip in a vertical direction, and
a lowermost end of each of the plurality of thermal interface material layers is on a same plane as or below a bottom surface of the semiconductor chip in the vertical direction.

20. The semiconductor package of claim 19, wherein the thermal vias include copper or an alloy of copper (Cu).
